(19) United States
(12) Patent Application Publication
(10) Pub. No.: US 2005/0054146 A1
(43) Pub. Date: Mar. 10, 2005

(54) Photo-mask process and method for manufacturing a thin film transistor using the process

(76) Inventors: Yung-Chang Chen, Miao-Li (TW); Jia-Pang Pang, Miao-Li (TW); Chien-Ting Lai, Miao-Li (TW)

Correspondence Address: WEI TE CHUNG;FOXCONN INTERNATIONAL, INC., 1650 MEMOREX DRIVE, SANTA CLARA, CA, 95050, US

(21) Appl. No.: 10/818,904

(22) Filed: Oct. 21, 2004

(30) Foreign Application Priority Data
Apr. 4, 2003 (TW) 92107712

(51) Int. Cl. H01L 21/00; H01L 21/84; H01L 21/44

(52) U.S. Cl. 438/158; 438/609

(57) ABSTRACT

A photo-mask process includes the steps of: spreading a film of photo resist on a carrier (30, 50), exposing the photo resist using a mask with a predefined pattern, developing the photo resist to obtain a photo resist layer (36, 60) with the predefined pattern, depositing a layer of predetermined material on the photo resist layer and the carrier, and removing the photo resist layer and the layer of predetermined material thereon. The photo-mask process can omit a conventional etching process. That is, the photo-mask process is simplified, and its cost is lower than that of conventional photo-mask processes. A related method for manufacturing a thin film transistor is also provided.

### BACKGROUND OF THE INVENTION

1. Field of the Invention

The present invention relates to a photo-mask process and a method for manufacturing a thin film transistor (TFT) using the process.

2. Description of Prior Art

Generally, a TFT liquid crystal display (LCD) has a plurality of pixels and a plurality of TFTs corresponding to the pixels. This technology gives the TFT LCD the characteristics of high picture quality, scalability, high color purity, and fast response times. Therefore TFT LCDs are widely used in portable TVs, personal computers, navigation appliances of vehicles, and so on. Each TFT is arranged at an intersection region, and is used as a switching element for selectively controlling on/off operation of a corresponding pixel electrode.

TFTs include top gate type TFTs and bottom gate type TFTs, which are thus named according to their different structures. Methods for manufacturing the two types of TFTs are correspondingly different.

A conventional method for manufacturing a top gate type TFT is disclosed in U.S. Pat. No. 5,889,292. The resulting TFT is represented in FIG. 18 hereof. The method includes the steps of:
providing a substrate 10, which may be made of glass or SiO₂ (silicon oxide);
forming a source 11 and a drain 12 on the substrate 10 by a first photo-mask process, which includes depositing, photolithography, etching, and so on; wherein the material of the source 11 and the drain 12 is P-doped (phosphor-doped) amorphous silicon, and the photolithography includes spreading a film of photo resist, exposing the photo resist using a mask with a predefined pattern, developing, and so on;
forming a channel layer 13 on the substrate 10 by a second photo-mask process, wherein the material of the channel layer 13 is P-type or intrinsic amorphous SiGe (silicon-germanium);
illuminating the formed structure using a laser light thereby causing the source 11, the drain 12 and the channel layer 13 to be crystallized;
forming an insulation layer 14 and a plurality of contact holes 15 by a third photo-mask process, wherein the material of the insulation layer 14 is silicon oxide; and
forming a source electrode 16, a drain electrode 17 and a gate electrode 18 by a fourth photo-mask process, thereby obtaining a top gate type thin film transistor, wherein the material of the source electrode 16, the drain electrode 17 and the gate electrode 18 is aluminum (Al), molybdenum (Mo), chromium (Cr) or another suitable material.

A conventional method for manufacturing a bottom gate type TFT is disclosed in U.S. Pat. No. 6,500,702. The resulting TFT is represented in FIG. 19 hereof. The method includes the steps of:
providing a substrate 20;
forming a gate electrode 21 and a storage capacitor electrode 22 on the substrate 10 by a first photo-mask process;
forming a gate insulation layer 23 on the above-described structure;
forming an amorphous silicon layer 24 and an ohmic contact layer 25 on the gate insulation layer 23 by a second photo-mask process, wherein the ohmic contact layer 25 is an adulteration semiconductor layer;
forming a source electrode 26 and a drain electrode 27 by a third photo-mask process;
forming a passivation layer 28 and a contact hole (not shown) communicating with the drain electrode 27 by a fourth photo-mask process; and
forming a pixel electrode 29 by a fifth photo-mask process.

In the two above-described patents, the photo-mask processes all include depositing, photolithography, etching and wiping off of the residual photo resist. Each etching process needs materials and equipment, making the cost of the photo-mask processes unduly high.

### SUMMARY OF THE INVENTION

An object of the present invention is to provide a relatively simple and inexpensive photo-mask process.

Another object of the present invention to provide a method for manufacturing a thin film transistor using the above-described photo-mask process.

In order to achieve the first object set forth, a photo-mask process of the present invention includes the steps of spreading a film of photo resist on a carrier, exposing the photo resist using a mask with a predefined pattern, developing the photo resist to obtain a photo resist layer with the predefined pattern, depositing a layer of predetermined material on the photo resist layer and the carrier, and removing the photo resist layer and the layer of predetermined material thereon.

The photo-mask process of the present invention can omit a conventional etching process. That is, the photo-mask process is simplified, and its cost is lower than that of conventional photo-mask processes.

In order to achieve the second object set forth, a method of the present invention for manufacturing a thin film transistor includes at least three photo-mask processes. At least one of the photo-mask processes includes the steps of spreading a film of photo resist on a carrier, exposing the photo resist using a mask with a predefined pattern, developing the photo resist to obtain a photo resist layer with the predefined pattern, depositing a layer of predetermined material on the photo resist layer and the carrier, and removing the photo resist layer and the layer of predetermined material thereon.

The above-described at least one photo-mask process of the present invention can omit a conventional etching process. That is, the photo-mask process is simplified, and the cost of manufacturing the thin film transistor is lower than that of conventional manufacturing methods.

Other objects, advantages and novel features of the invention will become more apparent from the following detailed description when taken in conjunction with the accompanying drawings; in which:

### BRIEF DESCRIPTION OF THE DRAWINGS

FIG. 1 to FIG. 8 respectively show schematic, cross-sectional views of structures successively formed in the course of manufacturing a TFT according to a first embodiment of the method of the present invention;

FIG. 9 to FIG. 17 respectively show schematic, cross-sectional views of structures successively formed in the course of manufacturing a TFT according to a second embodiment of the method of the present invention;

FIG. 18 is a schematic, cross-sectional view of a conventional top gate type TFT; and

FIG. 19 is a schematic, cross-sectional view of a conventional bottom gate type TFT.

### DETAILED DESCRIPTION OF THE INVENTION

A first embodiment of the method for manufacturing a TFT of the present invention includes the steps of:

Referring to FIG. 1, providing a substrate 30, which may be made of glass or silicon oxide (SiO₂);

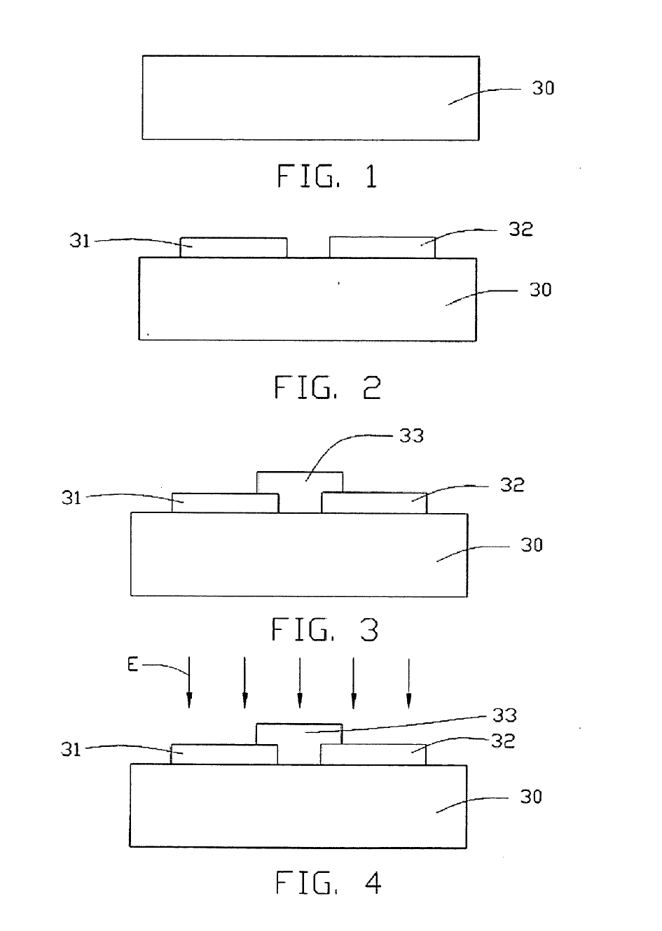

Referring to FIG. 2, performing a first photo-mask process comprising the steps of: depositing an amorphous silicon layer on the substrate 30, and forming a source 31 and a drain 32 on the substrate 30 by processes of photolithography, etching, and so on;

Referring to FIG. 3, performing a second photo-mask process comprising the steps of: depositing a P-type or intrinsic amorphous SiGe layer on the above-described structure, and thereby forming a channel layer 33 by processes of photolithography, etching, and so on;

Referring to FIG. 4, illuminating the above-described structure using a laser light E, so that the source 31, the drain 32 and the channel layer 33 are crystallized;

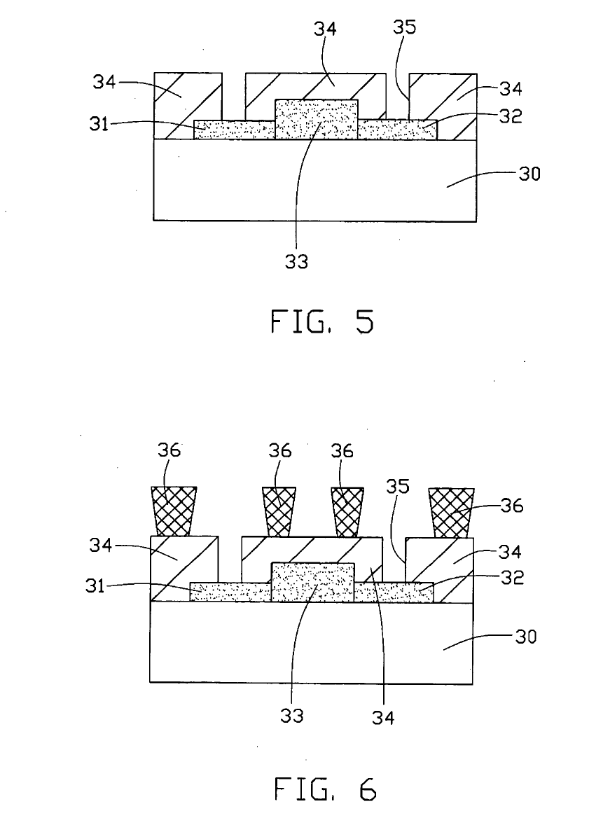

Referring to FIG. 5, performing a third photo-mask process comprising the steps of: depositing a silicon layer on the above-described structure, and thereby forming an insulation layer 34 and a plurality of contact holes 35 by processes of photolithography, etching, and so on;

Referring to FIG. 6: spreading a film of photo resist on the above-described structure, the photo resist being positive or negative; and exposing and developing the photo resist using a mask with a predefined pattern thereby forming a photo resist layer 36 with the predefined pattern, wherein the photo resist layer 36 may have widened tops and narrowed bottoms;

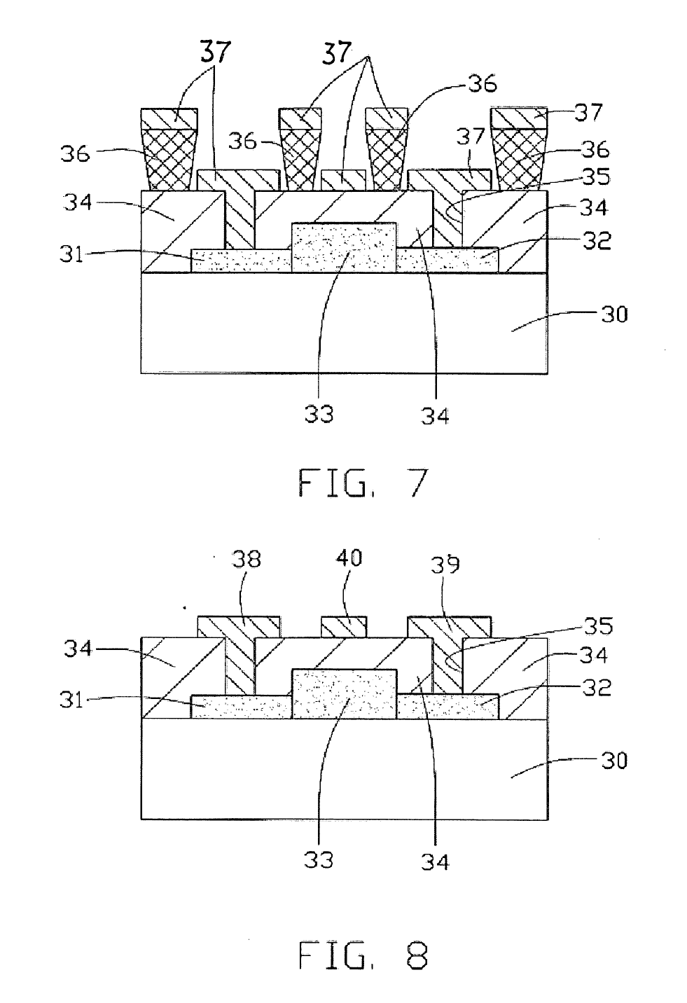

Referring to FIG. 7, evenly depositing a metal layer 37 on the above-described structure; wherein a material of the metal layer 37 is Al, Mo, Cr or another suitable material, and the metal layer 37 is thinner than the photo resist layer 36; and

Referring to FIG. 8, wiping off the photo resist layer 36 and portions of the metal layer 37 formed on the photo resist layer 36, with remaining portions of the metal layer 37 respectively forming a source electrode 38, a drain electrode 39 and a gate electrode 40, thereby obtaining a top gate type TFT.

FIG. 6 through FIG. 8 illustrate a fourth photo-mask process of the first embodiment of the method of the present invention. The fourth photo-mask process does not include an etching step. Materials and equipment for etching are not required, therefore the cost of manufacturing the TFT using the first embodiment of the method is reduced.

A second embodiment of the method for manufacturing a TFT of the present invention includes the steps of:

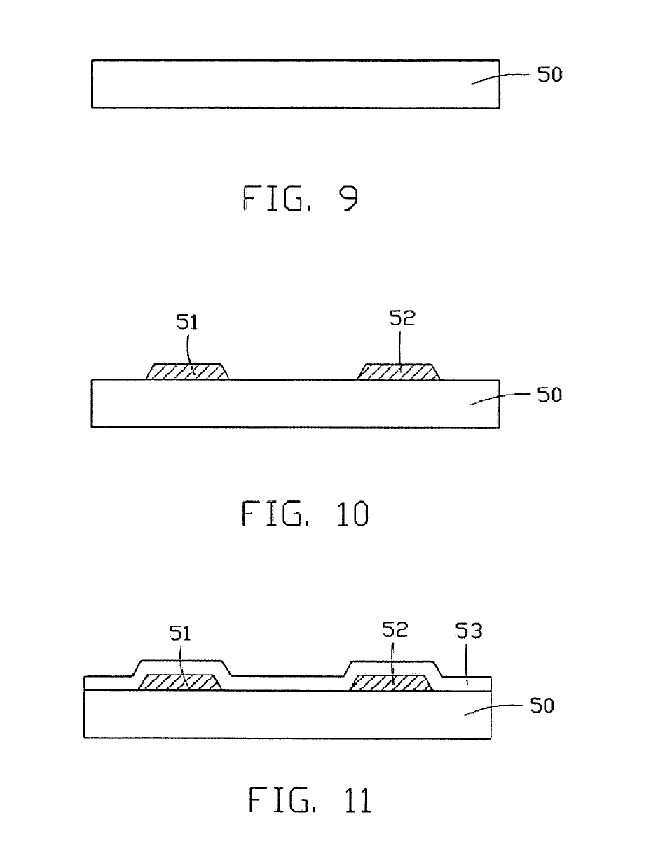

Referring to FIG. 9, providing a substrate 50, which may be made of glass or silicon oxide (SiO₂);

Referring to FIG. 10, performing a first photo-mask process comprising the steps of: depositing a metal layer on the substrate 50, and then forming a gate electrode 51 and a storage capacitor electrode 52, wherein a material of the metal layer is Ge, Al or another suitable material;

Referring to FIG. 11, depositing a silicon oxide layer on the above-described structure thereby forming a gate insulation layer 53;

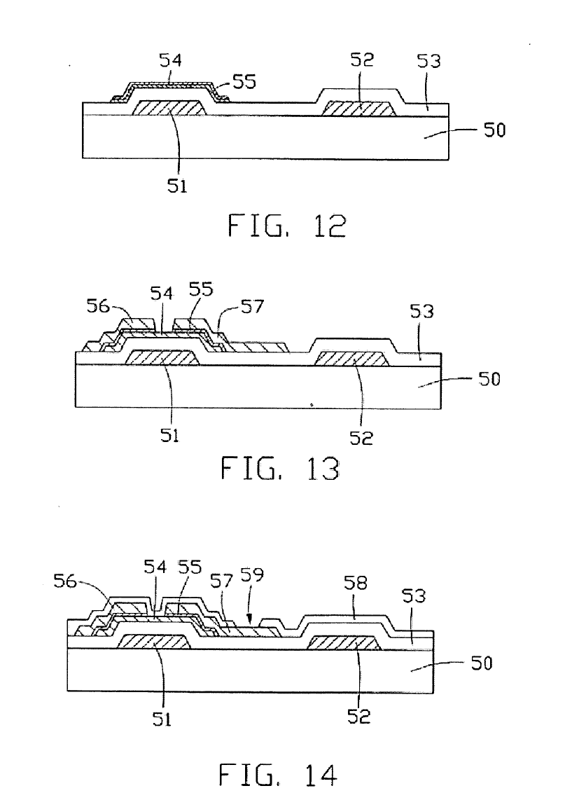

Referring to FIG. 12, performing a second photo-mask process comprising the steps of: depositing an amorphous silicon layer and an adulteration silicon layer on the above-described structure, and then respectively forming an active semiconductor layer 54 and an ohmic contact layer 55 by processes of photolithography, etching, and so on;

Referring to FIG. 13, performing a third photo-mask process comprising the steps of: depositing a metal layer on the above-described structure, and then forming a source electrode 56 and a drain electrode 57 by processes of photolithography, etching, and so on;

Referring to FIG. 14, performing a fourth photo-mask process comprising the steps of: depositing a silicon oxide layer on the above-described structure, and then forming a passivation layer 58 and a contact hole 59 communicating with the drain electrode 57 by processes of photolithography, etching, and so on;

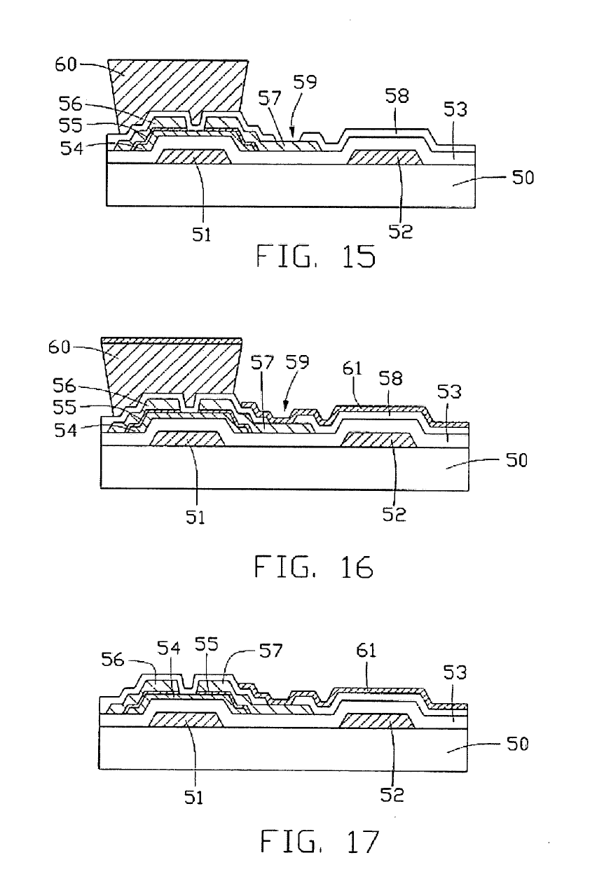

Referring to FIG. 15: spreading a film of photo resist on the above-described structure, the photo resist being positive or negative; and exposing and developing the photo resist using a mask with a predefined pattern thereby forming a photo resist layer 60 with the predefined pattern, wherein the photo resist layer 60 may have a widened top and a narrowed bottom;

Referring to FIG. 16, evenly depositing a transparent electrode on the above-described structure, wherein a material of the transparent electrode is indium tin oxide (ITO), indium zinc oxide (IZO) or another suitable material, and the transparent electrode is thinner than the photo resist layer 60; and

Referring to FIG. 17, wiping off the photo resist layer 60 and a portion of the transparent electrode formed on the photo resist layer 60, with a remaining portion of the transparent electrode forming a pixel electrode 61, thereby obtaining a bottom gate type TFT.

FIG. 15 to FIG. 17 illustrate a fifth photo-mask process of the second embodiment of the method of the present invention. The fifth photo-mask process does not include an etching step. Materials and equipment for etching are not required, therefore the cost of manufacturing the TFT using the second embodiment of the method is reduced.

Furthermore, a method of the present invention for manufacturing a TFT may include only three photo-mask processes. Moreover, all the photo-mask processes may omit the process of etching.

It is to be further understood that even though numerous characteristics and advantages of the present invention have been set forth in the foregoing description, together with details of the structures formed by practicing the invention, the disclosure is illustrative only, and changes may be made in detail, especially in matters of arrangement of steps and matters of shape, size, and arrangement of parts of said structures within the principles of the invention to the full extent indicated by the broad general meaning of the terms in which the appended claims are expressed.

1. A photo-mask process, comprising the steps of:
forming a film of photo resist on a carrier;
exposing the photo resist using a mask with a predefined pattern;
developing the photo resist to obtain a photo resist layer with the predefined pattern;
depositing a layer of predetermined material on the photo resist layer and the carrier; and
removing the photo resist layer and any portion or portions of the layer of predetermined material that are on the photo resist layer.

2. The photo-mask process of claim 1, wherein the photo resist is a positive photo resist or a negative photo resist.

3. The photo-mask process of claim 1, wherein the predetermined material is a metal.

4. The photo-mask process of claim 1, wherein the layer of predetermined material is a transparent electrode.

5. The photo-mask process of claim 4, wherein the predetermined material comprises indium tin oxide or indium zinc oxide.

6. The photo-mask process of claim 1, wherein the photo resist layer is thicker than the layer of predetermined material.

7. The photo-mask process of claim 1, wherein the photo resist layer has a widened top and a narrowed bottom.

8. A method for manufacturing a thin film transistor, the method comprising at least three photo-mask processes, wherein at least one of the photo-mask processes includes the steps of:
forming a film of photo resist on a carrier;
exposing the photo resist using a mask with a predefined pattern;
developing the photo resist to obtain a photo resist layer with the predefined pattern;
depositing a layer of predetermined material on the photo resist layer and the carrier; and
removing the photo resist layer and any portion or portions of the layer of predetermined material that are on the photo resist layer.

9. The method of claim 8, wherein the photo resist is a positive photo resist or a negative photo resist.

10. The method of claim 8, wherein the predetermined material is a metal.

11. The method of claim 8, wherein the layer of predetermined material is a transparent electrode.

12. The method of claim 11, wherein the predetermined material is indium tin oxide or indium zinc oxide.

13. The method of claim 8, wherein the photo resist layer is thicker than the layer of predetermined material.

14. The method of claim 8, wherein the photo resist layer has a widened top and a narrowed bottom.

15. The method of claim 8, wherein the thin film transistor is a top gate type thin film transistor.

16. The method of claim 8, wherein the thin film transistor is a bottom gate type thin film transistor.

17. The method of claim 8, wherein the method comprises three photo-mask processes.

18. The method of claim 8, wherein the method comprises four photo-mask processes.

19. The method of claim 8, wherein the method comprises five photo-mask processes.
